(19) United States
(12) Patent Application Publication
(10) Pub. No.: US 2009/0085068 A1
(43) Pub. Date: Apr. 2, 2009

(54) Semiconductor integrated circuit having output buffer circuit

(75) Inventor: Hiroyuki Furukawa, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/285,088

(22) Filed: Sep. 29, 2008

(30) Foreign Application Priority Data
Oct. 1, 2007 (JP) 2007-257433

(51) Int. Cl. H01L 29/66

(52) U.S. Cl. 257/207; 257/E29.166

(57) ABSTRACT

Provided is a semiconductor integrated circuit capable of preventing switching noise due to on/off switching of an output buffer transistor from being transmitted to circuits other then the output buffer transistor via power supply lines, wells, and a substrate. A semiconductor integrated circuit according to the present invention includes: a first power supply line connected to a source electrode of an output buffer transistor provided in a well formed on a semiconductor substrate; and a second power supply line connected to a well tap provided to correspond to the output buffer transistor, the first power supply line and the second power supply line being separately provided in different paths.

### BACKGROUND OF THE INVENTION

1. Field of the Invention

The present invention relates to a semiconductor integrated circuit having at least one output buffer circuit.

2. Description of Related Art

In recent years, microprocessors and system LSIs for digital signal processing have shown a remarkable progress in technology, including enhancement of functions mounted on a single chip by high integration and enhancement of operation speed. The progress toward the higher integration and higher operation speed raises a problem of causing a malfunction due to power supply noise in the design of high-speed digital LSIs.

Specifically, as the level of integration is further increased by scaling according to Moore's law, a gate oxide of a MOS transistor is further thinned, which leads to a reduction in power supply voltage inside an LSI. The reduction in power supply voltage results in a reduction in noise margin and an increase in effect of the power supply noise. Further, to achieve a high-speed operation, it is necessary to cause a large current to flow through an output buffer. As the current increases, the power supply noise increases. Even if a malfunction does not occur, AC characteristics such as jitter are deteriorated due to the power supply noise, which hinders the high-speed operation.

To prevent such malfunction due to the power supply noise, Japanese Unexamined Patent Application Publication No. 63-234623 discloses a semiconductor integrated circuit in which a power supply pad of an output buffer transistor and a power supply pad of an internal circuit other than the output buffer transistor are separately provided, thereby preventing a malfunction from occurring in the internal circuit due to switching noise of the output buffer transistor.

### SUMMARY

As a result of study, the inventor of the present invention has found that, even if a power supply of an output buffer transistor is separated from a power supply of an internal circuit, there is a fear that switching noise of an output buffer transistor affects an internal circuit via a semiconductor substrate, which may cause a malfunction of the internal circuit.

The reason for the above will be described with reference to FIGS. 1 to 4. FIG. 1 is a circuit diagram showing an output buffer circuit 208. An internal core 105 is connected to each of a VDD1 power supply and a GNDA power supply, and outputs a control signal 108 to the output buffer circuit 208. A prebuffer 101 receives the control signal 108, and outputs a control signal 106 for controlling on/off of a P-channel MOS buffer transistor 102 and a control signal 107 for controlling on/off of an N-channel MOS buffer transistor 103. The prebuffer 101 is connected to each of a VDD2 power supply and a GNDB power supply. A source electrode of the P-channel MOS buffer transistor 102 is connected to a VDD3 power supply, and a source electrode of the N-channel MOS buffer transistor 103 is connected to a GNDC power supply. Further, a drain electrode of the P-channel MOS buffer transistor 102 and a drain electrode of the N-channel MOS buffer transistor 103 are commonly connected to each other, and are further connected to an input/output pad 104. As the N-channel MOS buffer transistor 103 and the P-channel MOS buffer transistor 102, large transistors with high driving ability are used. Further, the input/output pad 104 is connected with an input buffer (not shown) as well as the output buffer circuit 208 so as to transmit a signal input from the input/output pad 104 to the internal core 105.

FIG. 2 is a schematic wiring diagram showing GND power supplies in the entirety of a single semiconductor integrated circuit. The output buffer circuit 208 is formed on the outer periphery of a semiconductor chip 201. An output of the output buffer circuit 208 is connected to the input/output pad 104 that is provided closer to the outer periphery of the semiconductor chip 201 than the output buffer circuit 208. A GND power supply is supplied from a GND pad 204, and power is supplied to an output buffer 109 of the output buffer circuit 208 via a GND line C (202) extending around the outer periphery of the semiconductor chip 201. Further, the GND pad 204 is also connected to a GND line B (206) serving as a GND power supply line leading to the prebuffer 101 of the output buffer circuit 208. Though the GND line B (206) is formed so as to extend around the outer periphery of the semiconductor chip 201 in the same manner as the GND line C (202), the GND line B (206) is provided on the inner side of the GND line C (202). Further, an internal core region 209 is provided on the inner side of the output buffer circuit 208. In the internal core region 209, GND lines A (207) are formed in a matrix form. In this case, each of the GND line A (207), the GND line B (206), and the GND line C (202) is supplied with power from the GND pad 204. Alternatively, as disclosed in Japanese Unexamined Patent Application Publication No. 63-234623, the GND line A (207), the GND line B (206), and the GND line C (202) may be individually provided with a GND pad. In other words, GND power supply lines provided in the semiconductor chip may be completely separated by the GND line A (207), the GND line B (206), and the GND line C (202). For simplification of the description, a single output buffer circuit 208 and a single input/output pad 104 are shown in FIG. 2 as a representative example, but in reality, a plurality of output buffer circuits 208 and a plurality of input/output pads 104, which are each supplied with power from the common GND wiring B (206) and GND line C (202), are arranged on the outer periphery of the semiconductor chip 201.

The output buffer circuit 208 is disposed as shown in the schematic layout diagram of FIG. 3 illustrating the output buffer circuit. The input/output pad 104 is disposed on the outermost periphery of the semiconductor chip 201, and the output buffer 109 is disposed on the inner side of the input/output pad 104. Further, the prebuffer 101 is disposed on the inner side of the output buffer 109, and the internal core 105 is provided on the inner side of the prebuffer 101. Each of the output buffer 109, the prebuffer 101, and the internal core 105 has a P-channel transistor forming region and an N-channel transistor forming region.

FIG. 4 is a wiring diagram showing GND power supplies of the output buffer circuit 208. Referring to FIG. 4, the GND line C (202) is connected to an Nch source/drain region 212, which is formed in an output buffer region 211, via contacts C1. The Nch source/drain region 212 serves as the source electrode of the N-channel MOS buffer transistor 103. Though not shown in FIG. 4, the drain electrode of the N-channel MOS buffer transistor 103 is connected to the input/output pad 104. Below the GND line C (202), a gate electrode 215 is disposed in a direction substantially orthogonal to the GND line C (202). Further, the GND line C (202) is connected to a P+TAP 401, which is a well tap region provided so as to surround the N-channel MOS buffer transistor 103, via contacts C2. A region surrounded by the P+TAP 401 is a P-well 302. The GND power supply is supplied to the P-well 302 from the GND line C (202) via the contacts C2 and the P+TAP 401.

Further, the GND line B (206) provided in a prebuffer region 210 is connected to a source electrode 213, which is formed of an Nch source/drain region of an N-channel MOS transistor of the prebuffer 101, via contacts C3. Though not shown in FIG. 4, the GND line B (206) is also connected to the P+TAP of the P-well provided in the prebuffer region 210.

Furthermore, the GND line A (207) is connected to a source electrode 214 formed of the Nch source/drain region of the N-channel MOS transistor of the internal core region 209, and to a P+TAP (not shown), via a contact C4. Note that the GND line A (207) and the GND line B (206) are directly connected to each other by a line 216.

FIG. 5 is a cross-sectional diagram showing the output buffer circuit 208 configured as shown in FIG. 3. In the semiconductor chip 201, each of the output buffer 109, the prebuffer 101, and the internal core 105 has a P-well serving as an N-channel transistor forming region and an N-well serving as a P-channel transistor forming region which are formed on a P-type substrate P-sub 301. Further, the GND line C (202) is connected to each of a source electrode 310 of the N-channel MOS buffer transistor 103 and the P+TAP 401 serving as the well tap of the P-well 302. The GND line B (206) is connected to a P-well 304 in which the N-channel MOS transistor of the prebuffer 101 is formed. The GND line A (207) is connected to a P-well 306 in which the N-channel MOS transistor of the internal core. Furthermore, the GND line B (206) and the GND line A (207) are directly connected to each other via the line 216.

In this case, the N-channel MOS buffer transistor 103 has a high driving ability, and has an output directly connected to the input/output pad 104, which increases a load capacity. Accordingly, the on/off switching of the N-channel MOS buffer transistor 103 causes a large current to flow through the GND line C (202). In addition, the impedance of the GND line C (202) is not zero, which leads to a large fluctuation in voltage of the source electrode 310 of the N-channel MOS buffer transistor 103. Moreover, since the GND line C (202) also functions as a power supply line leading to the P-well 302, the source electrode 310 of the N-channel MOS buffer transistor 103 is directly connected to the P-well 302. Accordingly, through the on/off switching of the N-channel MOS buffer transistor 103, the large fluctuation in voltage is also transmitted to the P-well 302.

Furthermore, the P-well 302, in which the N-channel MOS buffer transistor 103 is formed, the P-well 304, in which the N-channel MOS transistor of the prebuffer 101 is formed, and the P-well 306, in which the N-channel MOS transistor of the internal core 105 is formed, are electrically connected to one another via the P-type semiconductor substrate 301. Accordingly, the power supply noise of the GND line C (202) due to the on/off switching of the N-channel MOS buffer transistor 103 is also transmitted to the P-well 304 of the prebuffer region 210 and the P-well 306 of the internal core region 209 via the P-well 302 and the P-type semiconductor substrate 301. As a result, the power supply noise transmitted to the P-wells 304 and 306 via the GND line C (202), the P-well 302, and the P-type semiconductor substrate 301 causes a malfunction of the prebuffer 101 or the internal core 105, which leads to a deterioration in characteristics.

A semiconductor integrated circuit according to the present invention includes: a first power supply line connected to a source electrode of an output buffer transistor formed on wells; and a second power supply line connected to a well tap provided to correspond to the output buffer transistor, the first power supply line and the second power supply line being separately provided in different paths.

According to the present invention, the power supply line connected to the source electrode of the output buffer transistor and the power supply line connected to each of the wells of the output buffer transistor are separately provided in different paths. As a result, it is possible to prevent the switching noise due to the on/off switching of the output buffer transistor from being transmitted to circuits other than the output buffer via the power supply lines, the wells, and the substrate. Consequently, it is possible to prevent a malfunction due to the power supply noise and an adverse effect on the electrical characteristics.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a circuit diagram showing an output buffer circuit according to a comparative example of the present invention;

FIG. 2 is a schematic wiring diagram showing GND power supplies in the entirety of a single semiconductor integrated circuit according to the comparative example;

FIG. 3 is a schematic layout diagram showing the output buffer circuit according to the comparative example;

FIG. 4 is a wiring diagram showing GND power supplies of the output buffer circuit according to the comparative example;

FIG. 5 is a cross-sectional diagram showing an output buffer circuit section according to the comparative example;

FIG. 6 is a schematic wiring diagram showing GND power supplies in the entirety of a single semiconductor integrated circuit according to an embodiment of the present invention;

FIG. 7 is a cross-sectional diagram showing an output buffer circuit section according to the embodiment of the present invention;

FIG. 8 is a wiring diagram showing GND power supplies of the output buffer circuit section according to the embodiment of the present invention;

FIG. 9 is a connection diagram showing GND power supply lines according to the embodiment of the present invention;

FIG. 10 is a connection diagram showing GND power supply lines according to another embodiment of the present invention; and

FIG. 11 is a wiring diagram showing GND power supplies of an output buffer circuit section according to another embodiment of the present invention.

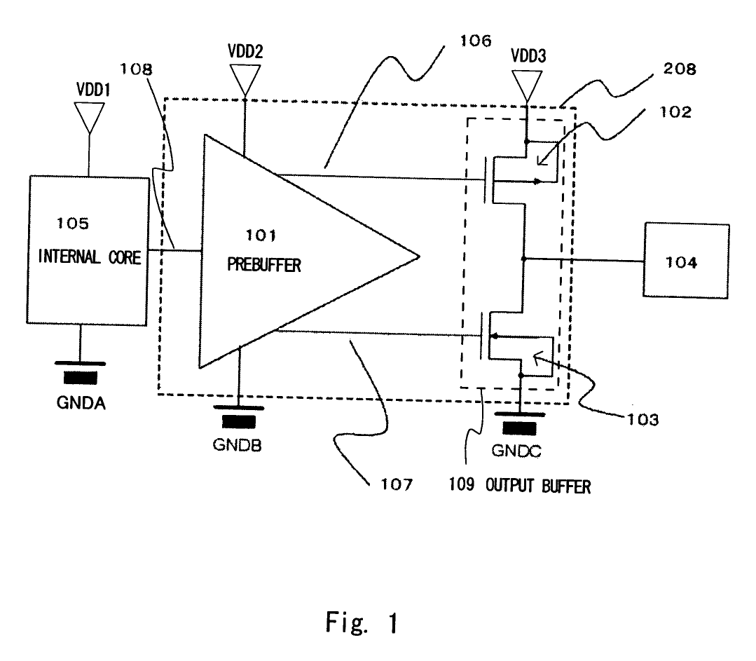

### DETAILED DESCRIPTION OF THE PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

According to the present invention, a power supply line (first power supply line) leading to an output buffer transistor itself and a power supply line (second power supply line) leading to a well tap of each well on which the output buffer transistor is formed are separated from each other, and power is supplied to the output buffer transistor and the well tap in different paths. If there are provided a plurality of output buffer transistors using a common power supply system, the power supply line leading to the well tap and the power supply line to the output buffer transistor itself are shared by the plurality of output buffers, to thereby prevent power supply noise from being transmitted to circuits other than the output buffers without unnecessarily increasing the number of power supply lines and a chip area. In particular, the effect of preventing the transmission of the power supply noise becomes more remarkable when the power supply line leading to the well tap and the power supply line leading to the output buffer itself are separately provided for the wells electrically connected to each other via a substrate.

Specifically, in the case of using a P-type substrate, such an effect becomes more remarkable when a power supply line leading to a well tap of a P-well forming an N-channel output buffer, and a power supply line leading to an N-channel buffer transistor are provided separately. Also in the case of using a P-channel buffer transistor, when a circuit other than the output buffer transistor is formed in a common well in which the output buffer transistor is formed, switching noise of the output buffer transistor can be prevented from causing noise of a transistor other than the output buffer transistor via the common well. Note that, in either case of providing the plurality of output buffer transistors in the common well or providing the plurality of output buffer transistors separately in different wells, by separately providing a source electrode of the output buffer transistor and a power supply line for supplying a well potential, the same effect can be obtained.

### Embodiments

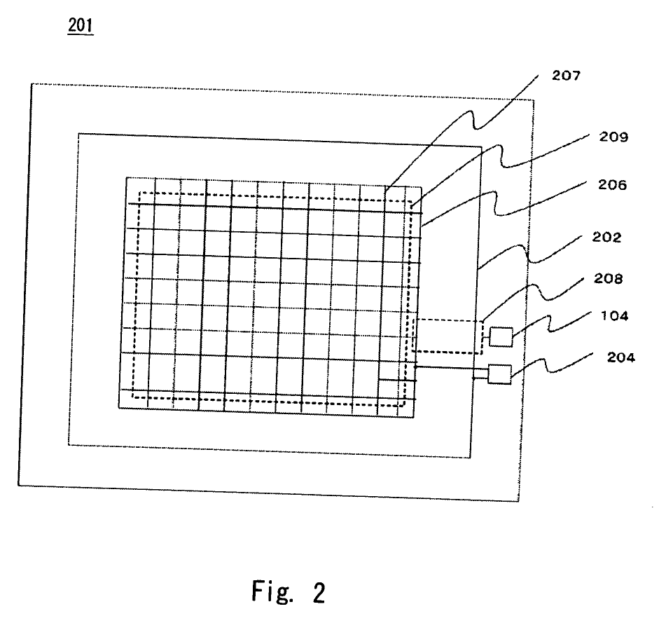

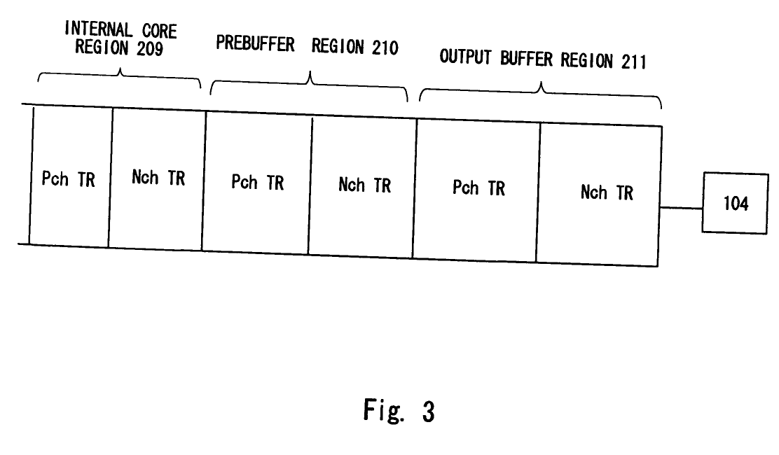

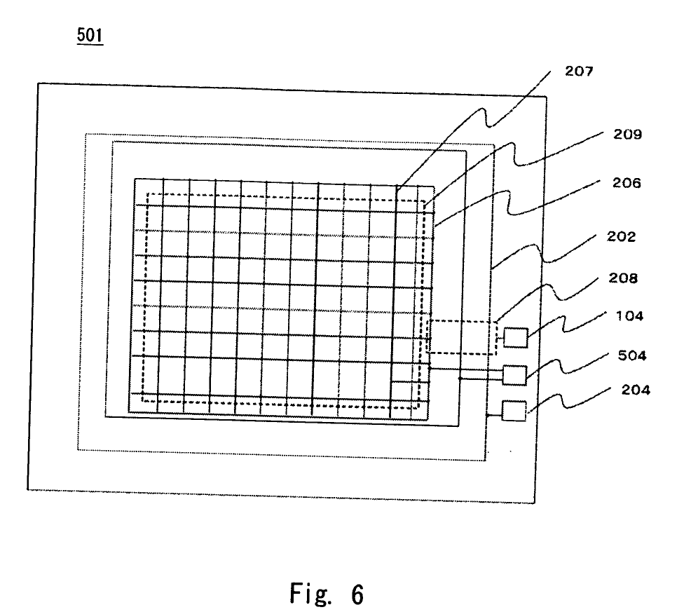

FIG. 6 is a schematic wiring diagram showing GND power supplies in the entirety of a single semiconductor integrated circuit according to an embodiment of the present invention. To prevent redundant explanation, components of FIG. 6 identical with those of FIG. 2 according to a comparative example of the present invention are denoted by the same reference symbols, and a description thereof is omitted. An output buffer circuit 508 is identical with an output buffer circuit 208 of the comparative example except for the connection between GND power supply lines and an output buffer 109. In this embodiment, a GND power supply pad 505 is provided in addition to a GND power supply pad 204. Further, a power supply line leading from the GND power supply pad 204 is connected only to the outer periphery of the semiconductor integrated circuit, and is not connected to an internal core region 209 and the like. The GND power supply pad 505 is connected to a GND line D (503). The GND line D (503) is connected on the inner side of a GND line C (202) and on the outer side of a GND line B (206) so as to extend around the outer periphery. The GND line C (202) functions as the first power supply line, and the GND power supply line 503 functions as the second power supply line. Furthermore, each of a GND line A (207) leading to the internal core region 209, and the GND line B (206) leading to a prebuffer region 110 is connected to the GND power supply pad 505 and is supplied with power from the GND power supply pad 505.

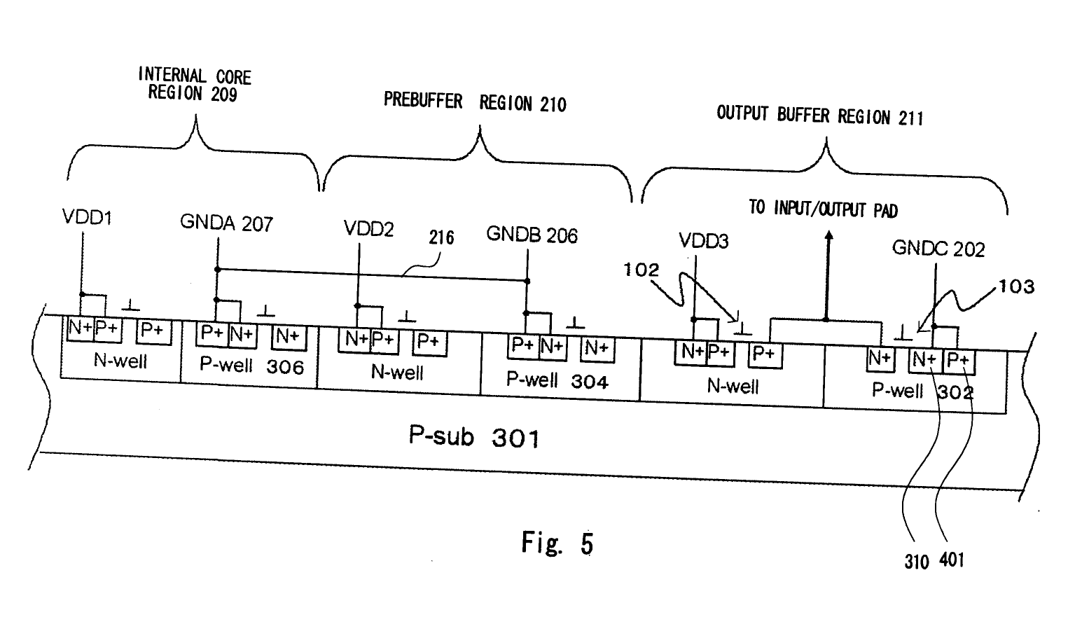

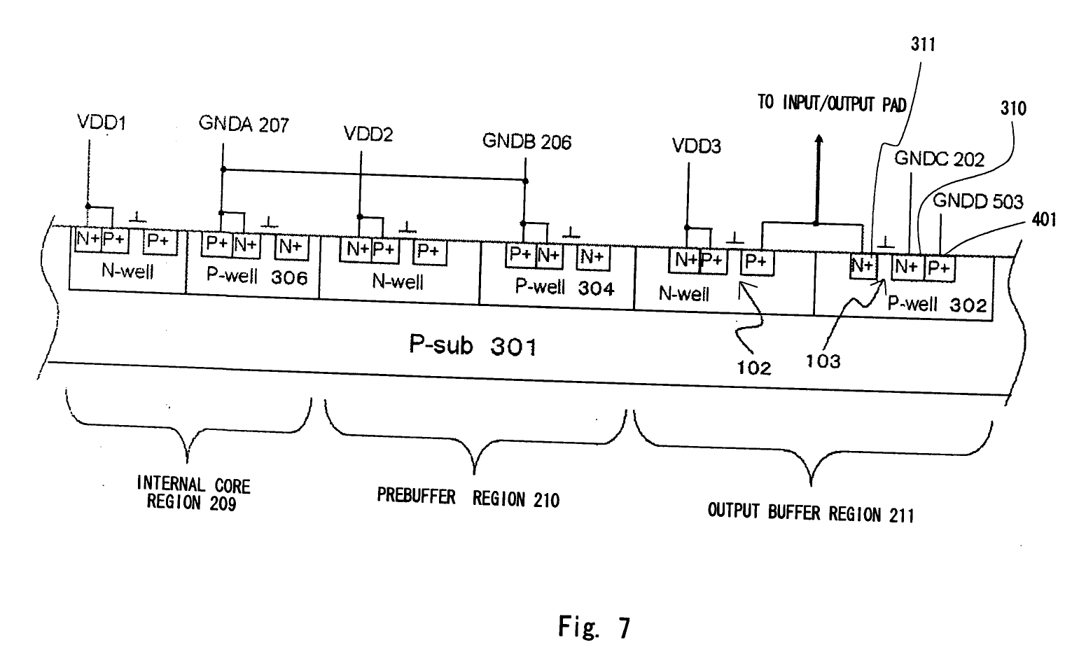

FIG. 7 is a cross-sectional diagram showing the output buffer circuit 508 according to the embodiment of the present invention. FIG. 7 is different from the cross-sectional diagram of FIG. 5 of the comparative example, in that the well potential is supplied from the GND line D (503) to a well tap 401 of a P-well 302 in which an N-channel MOS buffer transistor 103 is formed. The other components are identical with those of FIG. 5.

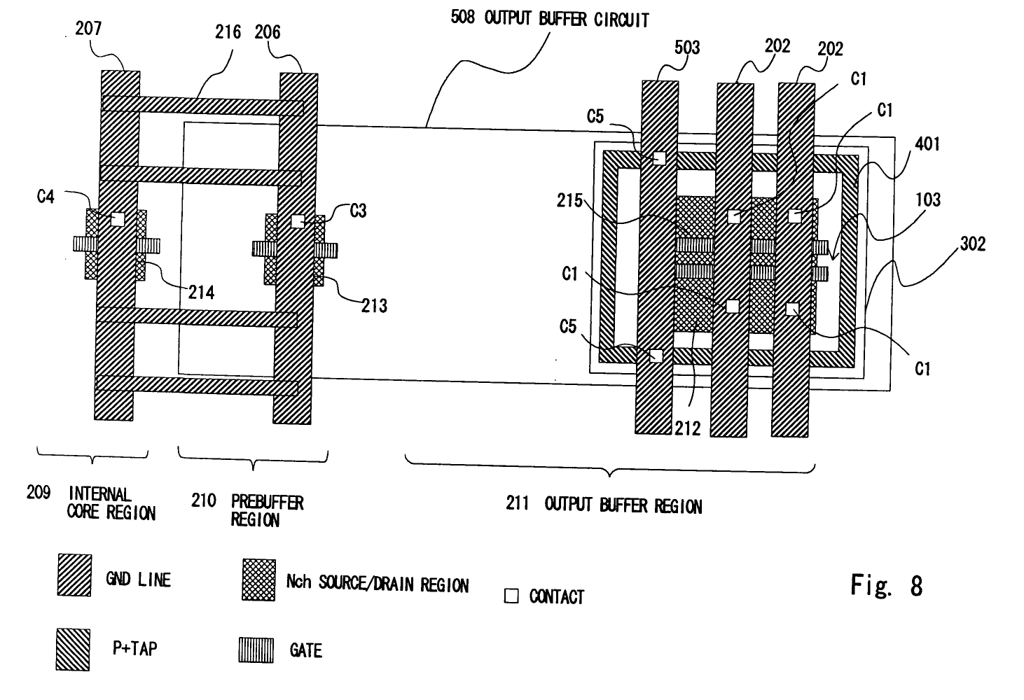

FIG. 8 is a wiring diagram showing GND power supplies of the output buffer circuit 508. Referring to FIG. 8, the GND line C (202) is connected to an Nch source/drain region 212 via contacts C1. The Nch source/drain region 212 connected to the GND line C (202) serves as a source electrode 310 of the N-channel MOS buffer transistor 103. Though not shown in FIG. 8, a drain electrode 311 of the N-channel MOS buffer transistor 103 is connected to an input/output pad 104. Further, the GND line D (503) is connected to the P+TAP 401 serving as a well tap provided to surround the N-channel MOS buffer transistor 103 via contacts C5. The P-well 302 is formed on the inner side of the P+TAP 401, and a GND power supply is supplied from the GND line D (503) via the contacts C5 and the P+TAP 401. Further, the GND line B (206) is connected to each of a source electrode 213 of an N-channel MOS transistor of a prebuffer 101 and a P+TAP (not shown) via contacts C3. The GND line A (207) is connected to each of a source electrode 214 of an N-channel MOS transistor of the internal core region 209, and a P+TAP (not shown) via contacts so as to supply the GND power supply thereto. Note that the GND line A (207) and the GND line B (206) are directly connected to each other by a line 216.

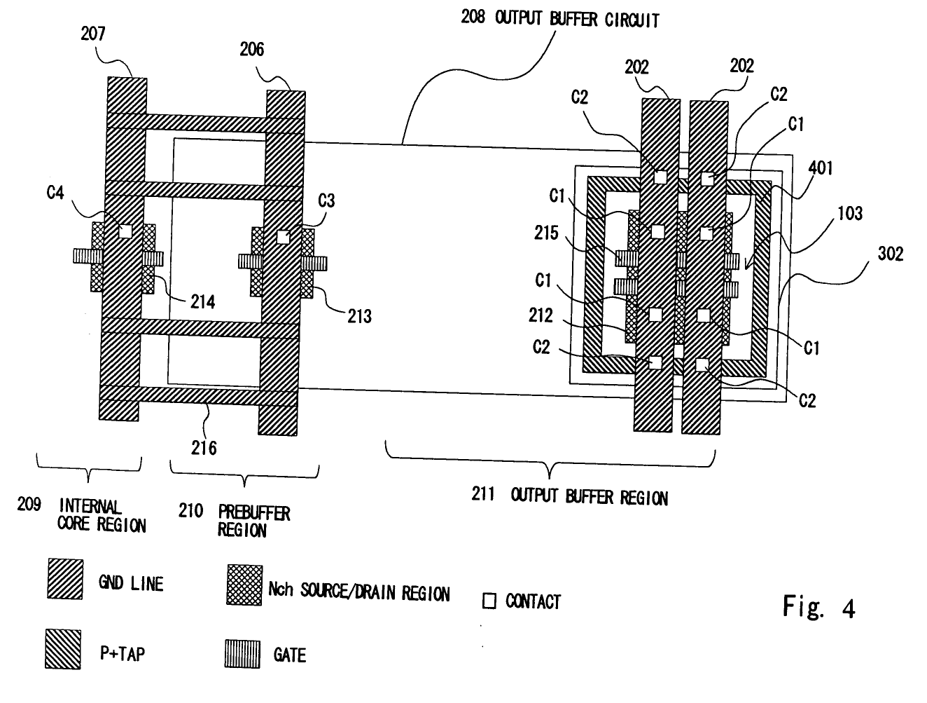

In the comparative example shown in FIG. 4, the GND power supply is supplied from the GND line C (202) commonly to the P+TAP 401 and the source electrode of the N-channel MOS buffer transistor 103. Meanwhile, the embodiment shown in FIG. 8 is different from the comparative example shown in FIG. 4 in that the GND power supply is supplied to the P+TAP 401 from the GND line D (503) different from the GND line C (202). The separation between the GND line C (202) and the GND line D (503) prevents power supply noise due to on/off switching of the output buffer transistor from being transmitted to the P-well 302 via the power supply line.

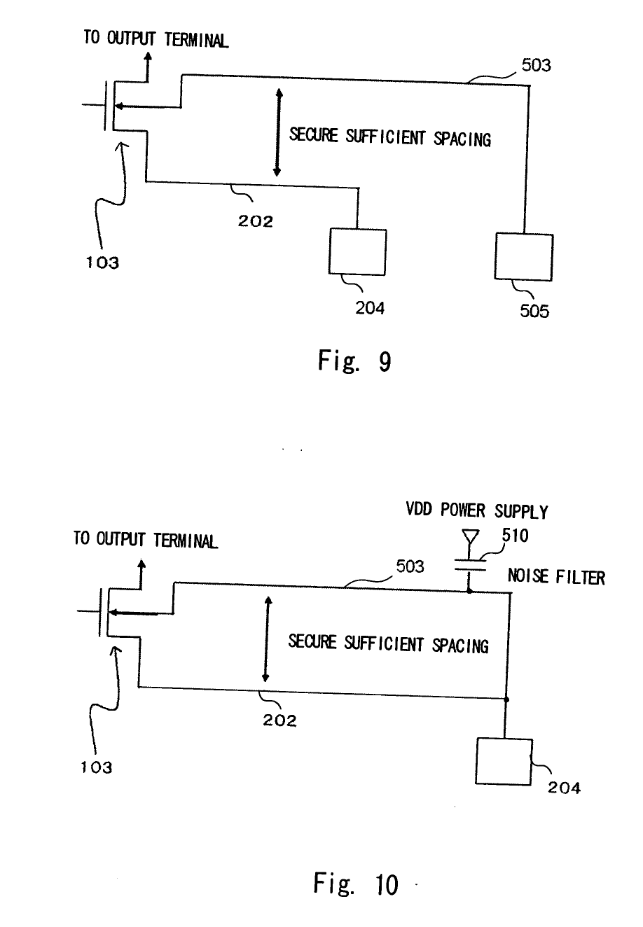

FIG. 9 is a connection diagram showing GND power supply lines according to the embodiment of the present invention. As described above, the source electrode 310 of the N-channel MOS buffer transistor 103 is connected to the GND power supply pad 204 via the GND line C (202), and a back gate of the N-channel MOS buffer transistor 103 is connected to the GND power supply pad 505 via the GND line D (503). The GND power supply pad 204 and the GND power supply pad 505 are connected to a common power supply outside the semiconductor chip 501, and are supplied with the same voltage. Further, the GND line C (202) and the GND line D (503) are spaced apart from each other in order to sufficiently reduce mutual inductance and coupling capacity therebetween. The GND lines are spaced apart from each other in order to prevent a fluctuation in potential or current of the GND line C (202) due to the on/off switching of the N-channel MOS buffer transistor 103, which leads to a fluctuation in potential of the GND line D (503) and which results in a fluctuation in power supply of the P-well or the. P-type substrate.

Next, a description is given of an example different from the above embodiment. FIG. 10 is a connection diagram showing GND power supply lines according to another embodiment of the present invention, which is different from the example shown in FIG. 9. Referring to FIG. 10, the GND line C (202) and the GND line D (503) are not individually provided with the GND power supply pad, but the power supply pad is shared therebetween, unlike FIG. 9. Note that the GND line C (202) and the GND line D (503) are sufficiently spaced apart from each other in order to sufficiently reduce mutual inductance and coupling capacity therebetween. On the GND line D (503), a capacitance 510 is provided as a noise filter between the GND line D (503) and a VDD power supply. The GND line D (503) is a line used for supplying the well potential. Since there is no need to cause a large current to flow through the GND line D (503), a wiring resistance is relatively large, and the fluctuation in power supply of the GND line D (503) is suppressed due to the wiring resistance and the capacitance. The capacitance can be realized by providing a decoupling cell as a gate capacitance in a free space of the outer periphery or the internal core, for example.

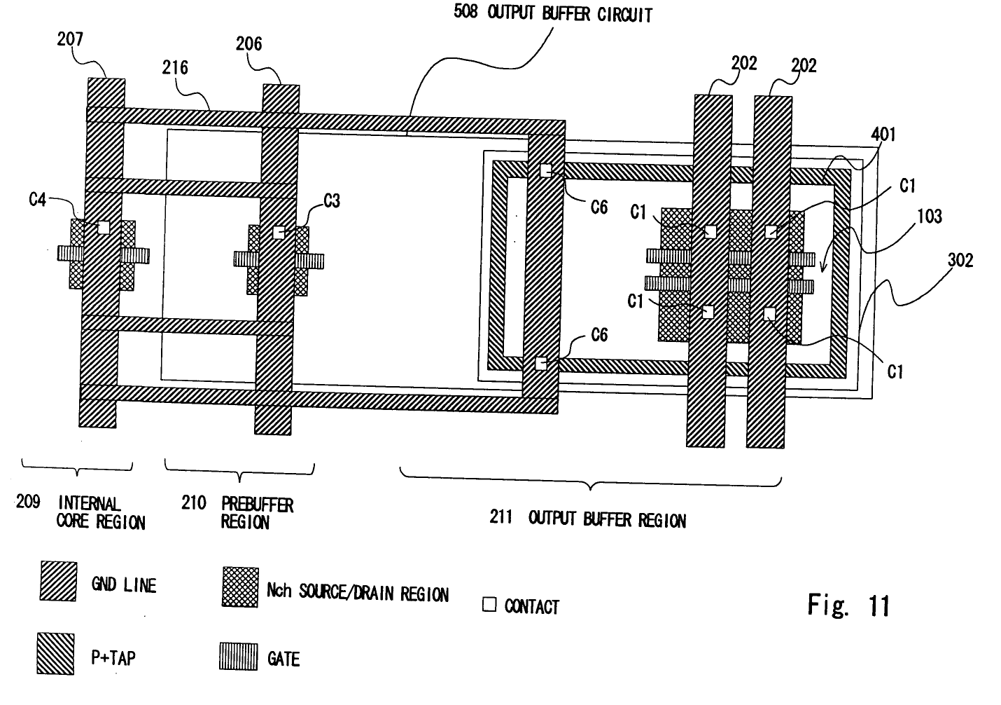

Next, FIG. 11 shows a wiring diagram showing GND power supplies according to another embodiment of the present invention. Referring to FIG. 11, power of the P+TAP 401 is supplied from the GND line B (206). In the embodiment shown in FIG. 11, there is no need to route the GND line D (503) around the outer periphery of the chip.

The preferred embodiments have been described above, but the present invention can be carried out by modifying the embodiments in various manners. For example, though the above embodiments have described the case where the line leading to the source electrode of the N-channel buffer transistor provided in the P-well formed on the P-type semiconductor substrate is separated from the line leading to the P-well, the present invention can also be applied to a case where a line leading to a source electrode of a P-channel buffer transistor provided in an N-well formed on an N-type semiconductor substrate is separated from a line leading to the N-well.

It is apparent that the present invention is not limited to the above embodiment but may be modified and changed without departing from the scope and spirit of the invention.

What is claimed is:

1. A semiconductor integrated circuit, comprising:
a semiconductor substrate;
wells formed on the semiconductor substrate;
at least one output buffer transistor formed in the wells;
at least one well tap provided to correspond to the output buffer transistor;
a first power supply line connected to a source electrode of the output buffer transistor; and
a second power supply line connected to the well tap, the first power supply line and the second power supply line being separately provided in different paths.

2. A semiconductor integrated circuit, comprising:
a semiconductor substrate;
wells formed on the semiconductor substrate;
a plurality of output buffer transistors formed in at least a part of the wells;
a plurality of well taps provided to respectively correspond to the plurality of output buffer transistors;
a first power supply line connected in common to source electrodes of the plurality of output buffer transistors; and
a second power supply line connected in common to the plurality of well taps, the first power supply line and the second power supply line being separately provided in different paths,
wherein the first power supply line and the second power supply line are each connected to a common power supply.

3. The semiconductor integrated circuit according to claim 1, wherein:
the at least one output buffer transistor comprises a plurality of output buffer transistors, and the at least one well tap comprises a plurality of well taps respectively corresponding to the plurality of output buffer transistors;
the first power supply line is connected in common to source electrodes of the plurality of output buffer transistors; and
the second power supply line is connected in common to the plurality of well taps.

4. The semiconductor integrated circuit according to claim 1, wherein the first power supply line and the second power supply line are each connected to a common power supply.

5. The semiconductor integrated circuit according to claim 1, wherein:
the semiconductor substrate has transistors other than the output buffer transistor, formed thereon; and
at least a part of the transistors are formed in one of the well having the output buffer transistor formed therein, and the well electrically connected to the well having the output buffer transistor formed therein, via the semiconductor substrate.

6. The semiconductor integrated circuit according to claim 2, wherein:
the semiconductor substrate has transistors other than the output buffer transistor, formed thereon; and
at least a part of the transistors are formed in one of the well having the output buffer transistor formed therein, and the well electrically connected to the well having the output buffer transistor formed therein, via the semiconductor substrate.

7. The semiconductor integrated circuit according to claim 1, wherein the semiconductor substrate and the wells have the same conductivity type.

8. The semiconductor integrated circuit according to claim 2, wherein the semiconductor substrate and the wells have the same conductivity type.

9. The semiconductor integrated circuit according to claim 1, further comprising an internal core region formed on the semiconductor substrate,
wherein the first power supply line and the second power supply line are each formed to extend around the internal core region.

10. The semiconductor integrated circuit according to claim 2, further comprising an internal core region formed on the semiconductor substrate,
wherein the first power supply line and the second power supply line are each formed to extend around the internal core region.

11. The semiconductor integrated circuit according to claim 1, wherein the first power supply line and the second power supply line are formed so as to be spaced apart from each other to sufficiently reduce mutual inductance and coupling capacity therebetween.

12. The semiconductor integrated circuit according to claim 2, wherein the first power supply line and the second power supply line are formed so as to be spaced apart from each other to sufficiently reduce mutual inductance and coupling capacity therebetween.

13. The semiconductor integrated circuit according to claim 1, further comprising a noise filter connected to the second power supply line.

14. The semiconductor integrated circuit according to claim 2, further comprising a noise filter connected to the second power supply line.

15. The semiconductor integrated circuit according to claim 1, further comprising:
a first power supply pad connected to the first power supply line; and
a second power supply pad connected to the second power supply line,
wherein the first power supply pad and the second power supply pad are formed on the semiconductor substrate, and are connected to each other outside the semiconductor substrate.

16. The semiconductor integrated circuit according to claim 2, further comprising:
a first power supply pad connected to the first power supply line; and
a second power supply pad connected to the second power supply line,
wherein the first power supply pad and the second power supply pad are formed on the semiconductor substrate, and are connected to each other outside the semiconductor substrate.

17. The semiconductor integrated circuit according to claim 1, further comprising a power supply pad connected in common to the first power supply line and the second power supply line,
wherein the first power supply line and the second power supply line are lines branched from the power supply pad.

18. The semiconductor integrated circuit according to claim 2, further comprising a power supply pad connected in common to the first power supply line and the second power supply line,
wherein the first power supply line and the second power supply line are lines branched from the power supply pad.
